(19) United States
(12) Patent Application Publication
(10) Pub. No.: US 2025/0038061 A1
(43) Pub. Date: Jan. 30, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chih-Hsien CHIU, Taichung City (TW); Wen-Jung TSAI, Taichung City (TW); Chia-Yang CHEN, Taichung City (TW); Chien-Ming CHANG, Taichung City (TW); Po-Hsin TSAI, Taichung City (TW)

(21) Appl. No.: 18/412,005

(22) Filed: Jan. 12, 2024

(30) Foreign Application Priority Data
Jul. 24, 2023 (TW) 112127585

(51) Int. Cl. H01L 23/367; H01L 21/56; H01L 23/00; H01L 23/31; H01L 23/498; H01L 23/552

(52) U.S. Cl. CPC H01L 23/367; H01L 21/56; H01L 23/3128; H01L 23/49822; H01L 23/552; H01L 24/16; H01L 24/32; H01L 24/48; H01L 24/81; H01L 24/83; H01L 24/85; H01L 24/33; H01L 24/73; H01L 2224/16227; H01L 2224/32225; H01L 2224/32245; H01L 2224/33181; H01L 2224/48227; H01L 2224/73204; H01L 2224/73215; H01L 2224/73253; H01L 2224/81; H01L 2224/83; H01L 2224/85

(57) ABSTRACT

An electronic package and a manufacturing method thereof are provided, in which an electronic component and a heat dissipation structure having an opening are arranged on a carrier structure, a heat sink is arranged in the opening and bonded to the electronic component, and the electronic component, the heat dissipation structure and the heat sink are covered with an encapsulation layer, such that the heat sink can be arranged according to a heat source of a specific part of the electronic component so as to effectively dissipate heat.

### BACKGROUND

### 1. Technical Field

The present disclosure relates to a packaging process, and more particularly, to an electronic package with a heat dissipation structure and manufacturing method thereof.

### 2. Description of Related Art

With the vigorous development of portable electronic products in recent years, various related products are gradually developing toward the trend of high density, high performance, lightness, thinness, shortness and smallness, wherein various types of semiconductor package structures applied to those portable electronic products are thus coordinated with innovation to meet the requirements of lightness, thinness, shortness, smallness and high density.

As shown in FIG. 1, a conventional semiconductor package 1 is provided with a semiconductor component 11 and a passive element 18 arranged on the top and bottom sides of a circuit structure 10, and the semiconductor component 11 and the passive element 18 are covered by a molding compound 14. Contacts 100 (inputs/outputs) of the circuit structure 10 are exposed from the molding compound 14, and then a plurality of solder balls 19 are formed on the contacts 100, so that the semiconductor package 1 is connected to an electronic device (not shown) such as a circuit board via the solder balls 19 in the subsequent process.

However, in the conventional semiconductor package 1, the semiconductor component 11 and the passive element 18 may generate a large amount of heat during the operation, and the molding compound 14 covering the semiconductor component 11 and the passive element 18 is made of a poor heat transfer material that has a thermal conductivity of only 0.8 Wm⁻¹k⁻¹ (i.e., the heat dissipation efficiency is poor), so that the aforesaid heat cannot be effectively dissipated, and even may cause damage to the semiconductor component 11 and the passive element 18, thereby seriously affecting product reliability.

Therefore, how to overcome the aforementioned drawbacks of the prior art has become an urgent issue to be addressed at present.

### SUMMARY

In view of the various shortcomings of the prior art, the present disclosure provides an electronic package, the electronic package comprises: a carrier structure having a circuit layer; an electronic component disposed on the carrier structure and electrically connected to the circuit layer; a heat sink disposed on the electronic component; an encapsulation layer formed on the carrier structure and covering the electronic component and the heat sink; and a heat dissipation structure having an opening and embedded in the encapsulation layer, wherein the heat sink is located in the opening.

The present disclosure also provides a method of manufacturing an electronic package, the method comprises: providing a carrier structure having a circuit layer; disposing an electronic component and a heat dissipation structure having an opening on the carrier structure, wherein the electronic component is electrically connected to the circuit layer, wherein a position of the opening corresponds to the electronic component, and the electronic component is correspondingly exposed from the opening; disposing at least one heat sink in the opening and on the electronic component; and forming an encapsulation layer on the carrier structure to cover the electronic component, the heat dissipation structure and the heat sink.

In the aforementioned electronic package and method, the electronic component is electrically connected to the circuit layer via a plurality of conductive bumps or a plurality of wires.

In the aforementioned electronic package and method, a width or an area of the heat sink is less than or equal to a width or an area of the electronic component.

In the aforementioned electronic package and method, the heat sink is bonded to the electronic component via an adhesive material.

In the aforementioned electronic package and method, an outer surface of the heat sink and an outer surface of the encapsulation layer are coplanar.

In the aforementioned electronic package and method, an outer surface of the heat sink, an outer surface of the heat dissipation structure and an outer surface of the encapsulation layer are coplanar.

In the aforementioned electronic package and method, the heat dissipation structure is exposed from a side surface of the encapsulation layer.

In the aforementioned electronic package and method, the electronic component is covered by the heat dissipation structure.

In the aforementioned electronic package and method, the heat dissipation structure comprises a sheet-shaped body surrounding the heat sink. For instance, the heat dissipation structure further comprises at least one supporting leg connected to the sheet-shaped body, and the supporting leg is bonded to the carrier structure.

In the aforementioned electronic package and method, a plurality of the heat sinks are arranged on the electronic component.

In the aforementioned electronic package and method, the present disclosure further comprises forming a shielding layer on the encapsulation layer, wherein the shielding layer is in contact with the heat dissipation structure.

In the aforementioned electronic package and method, the heat sink protrudes from a side surface of the electronic component.

As can be seen from the above, in the electronic package and the manufacturing method thereof according to the present disclosure, the heat sink can be arranged according to the heat source of a specific part of the electronic component, so the flexibility of use is great and the arrangement area is small. Hence, compared to the prior art, the electronic package of the present disclosure can effectively dissipate heat during operation and have a low cost.

Moreover, the manufacturing method of the present disclosure can use existing materials, processes and machines without adding new processes and materials or purchasing new equipment. Hence, the manufacturing method of the present disclosure can effectively control the cost of the processes, so that the electronic package of the present disclosure is economical.

### BRIEF DESCRIPTION OF THE DRAWINGS

FIG. 1 is a schematic cross-sectional view of a conventional semiconductor package.

FIG. 2A, FIG. 2B, FIG. 2C-1, FIG. 2D, FIG. 2E, FIG. 2F and FIG. 2G-1 are schematic cross-sectional views illustrating a method of manufacturing an electronic package according to a first embodiment of the present disclosure.

FIG. 2C-2 is a schematic partial top view of FIG. 2C-1.

FIG. 2G-2 is a schematic cross-sectional view illustrating another aspect of FIG. 2G-1.

FIG. 3A and FIG. 3B are schematic cross-sectional views illustrating other aspects of FIG. 2G-1.

FIG. 4A-1, FIG. 4B and FIG. 4C are schematic cross-sectional views illustrating an electronic package according to a second embodiment of the present disclosure.

FIG. 4A-2 is a schematic partial top view of FIG. 4A-1.

FIG. 5A and FIG. 5B are schematic cross-sectional views illustrating an electronic package according to a third embodiment of the present disclosure.

FIG. 6 is a schematic cross-sectional view illustrating an electronic package according to a fourth embodiment of the present disclosure.

### DETAILED DESCRIPTION

The following describes the implementation of the present disclosure with examples. Those familiar with the art can easily understand the other advantages and effects of the present disclosure from the content disclosed in this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships, or adjustments of the sizes, are to be construed as falling within the range covered by the technical content disclosed herein to the extent of not causing changes in the technical effects created and the objectives achieved by the present disclosure. Meanwhile, terms such as “on,” “above,” “first,” “second,” “a,” “one,” and the like are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

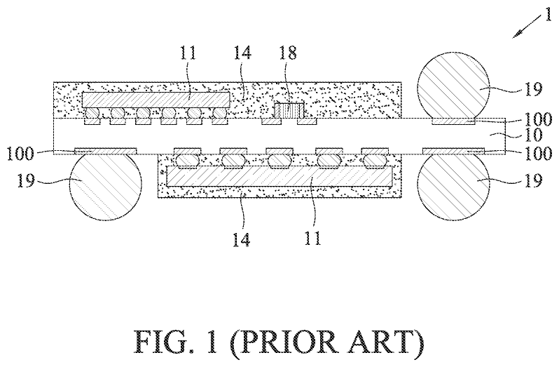

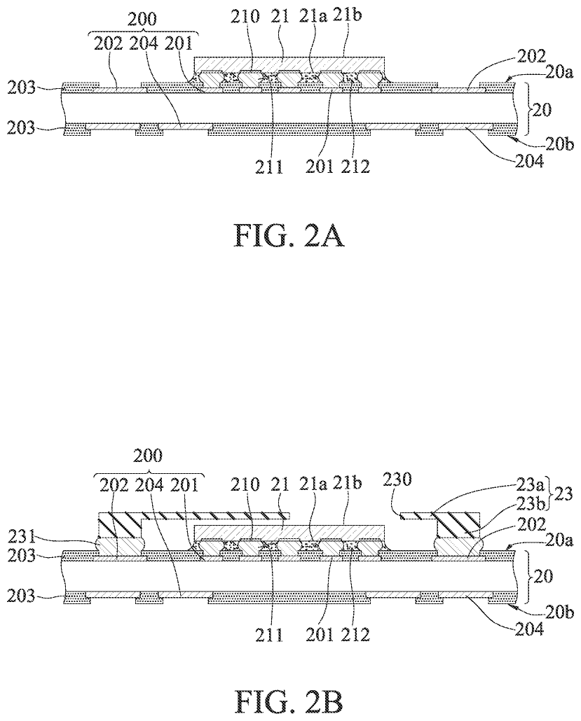

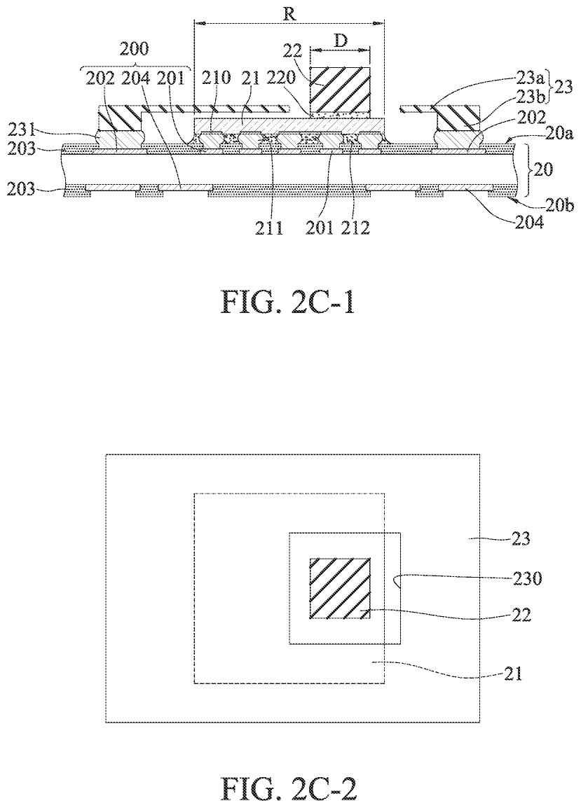

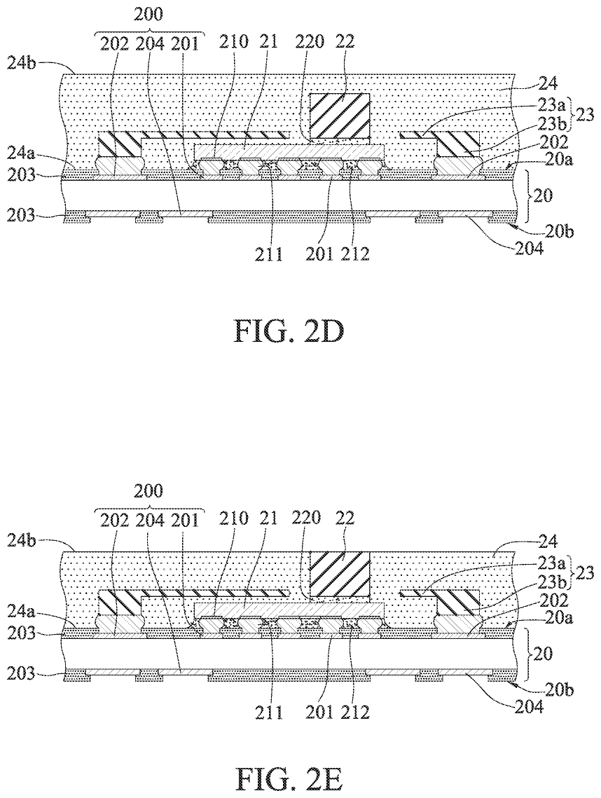

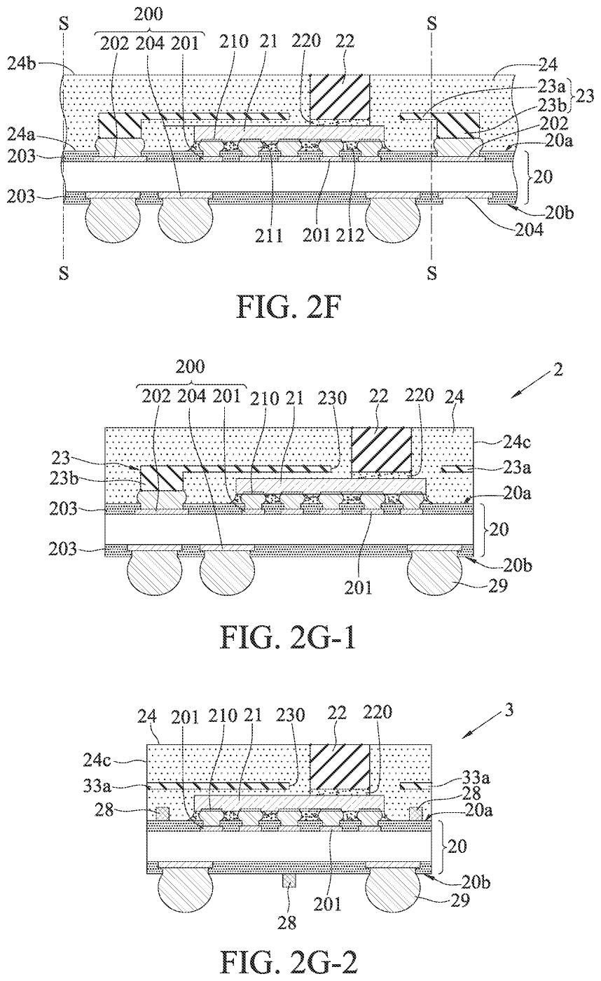

FIG. 2A, FIG. 2B, FIG. 2C-1, FIG. 2D, FIG. 2E, FIG. 2F and FIG. 2G-1 are schematic cross-sectional views illustrating a method of manufacturing an electronic package 2 according to a first embodiment of the present disclosure.

As shown in FIG. 2A, a carrier structure 20 is provided and has a first side 20a and a second side 20b opposing the first side 20a, and at least one electronic component 21 is disposed on the first side 20a of the carrier structure 20. For instance, the first side 20a of the carrier structure 20 is used as a die placement side for carrying the electronic component 21, and the second side 20b of the carrier structure 20 is used as a ball placement side.

The carrier structure 20 can be a package substrate with a core layer and a circuit portion or a coreless circuit structure.

In an embodiment, the carrier structure 20 comprises a dielectric layer and a circuit layer 200 formed on the dielectric layer, such as of a fan-out type redistribution layer (RDL) specification. For instance, the dielectric layer is made of Ajinomoto build-up film (ABF), polybenzoxazole (PBO), polyimide (PI), prepreg (PP), or other dielectric materials.

Moreover, the circuit layer 200 is formed with a plurality of external pads 202 and a plurality of electrical contact pads 201 on the first side 20a, and a plurality of ball placement pads 204 on the second side 20b. In addition, an insulating protective layer 203 such as a solder-resist layer is formed respectively on the first side 20a and the second side 20b, so that the external pads 202 and the electrical contact pads 201 of the first side 20a and the ball placement pads 204 of the second side 20b are respectively exposed from the insulating protective layer 203.

It should be understood that the carrier structure 20 can also be other carrying units for carrying chips, such as a silicon interposer, but not limited to the above.

The electronic component 21 is an active element, a passive element, or a combination of the active element and the passive element, wherein the active element is such as a semiconductor chip, and the passive element is such as a resistor, a capacitor, or an inductor.

In an embodiment, the electronic component 21 is a semiconductor chip and has an active surface 21a and an inactive surface 21b opposing the active surface 21a, and the active surface 21a has a plurality of electrode pads 210, such that the plurality of electrode pads 210 are bonded with and electrically connected to the electrical contact pads 201 of the carrier structure 20 via a plurality of conductive bumps 211 made of such as solder materials in a flip-chip manner, and a cladding layer 212 such as an underfill is filled and formed between the first side 20a of the carrier structure 20 and the active surface 21a of the electronic component 21 to cover the plurality of conductive bumps 211.

As shown in FIG. 2B, a heat dissipation structure 23 with an opening 230 is disposed on the first side 20a of the carrier structure 20, such that the opening 230 is correspondingly positioned above the electronic component 21, so part of the inactive surface 21b is exposed from the opening 230.

In an embodiment, the heat dissipation structure 23 is a heat dissipation frame made of such as copper material, and the heat dissipation structure 23 comprises a sheet-shaped body 23a with the opening 230 and a plurality of supporting legs 23b erected on the sheet-shaped body 23a, such that the sheet-shaped body 23a is spaced apart from the inactive surface 21b, so that the sheet-shaped body 23a covers part of the inactive surface 21b of the electronic component 21, and the supporting legs 23b are bonded onto the external pads 202 via a bonding layer 231 made of such as an adhesive material.

As shown in FIG. 2C-1 and FIG. 2C-2 (i.e., the schematic partial top view of FIG. 2C-1), a single heat sink 22 (e.g., a heat dissipation element) is formed in the opening 230, so that the heat sink 22 is bonded onto the inactive surface 21b of the electronic component 21, and the sheet-shaped body 23a surrounds the heat sink 22.

In an embodiment, the heat sink 22 is sheet-shaped, block-shaped, or fin-shaped, and a width D of the heat sink 22 is less than (or equal to) a width R of the electronic component 21 (or the area of the heat sink 22 is less than or equal to the area of the electronic component 21), so that the heat sink 22 is arranged according to the heat source of a specific part of the electronic component 21 without needing fully cover the electronic component 21 so as to improve the flexibility of use and the efficiency of heat dissipation. In addition, the material of the heat sink 22 can be metal or silicon, and the heat sink 22 can be a metal block or a dummy die in specific embodiments.

Moreover, the heat sink 22 protrudes from the opening 230 and is disposed on the inactive surface 21b of the electronic component 21 via an adhesive material 220.

Furthermore, the adhesive material 220 is a die attach film (DAF) or a metal paste (such as a tin paste, a silver paste) or the like.

As shown in FIG. 2D, an encapsulation layer 24 is formed on the first side 20a of the carrier structure 20, such that the encapsulation layer 24 covers the electronic component 21, the cladding layer 212, the heat sink 22 and the heat dissipation structure 23.

In an embodiment, the encapsulation layer 24 is defined to have a first surface 24a and a second surface 24b opposing the first surface 24a, such that the encapsulation layer 24 is bonded onto the first side 20a of the carrier structure 20 via the first surface 24a thereof.

Besides, the encapsulation layer 24 can be made of an insulating material, such as polyimide (PI), dry film, molding compound with epoxy resin, or other appropriate materials. For instance, the encapsulation layer 24 is formed on the carrier structure 20 by lamination or molding.

As shown in FIG. 2E, part of material of the second surface 24b of the encapsulation layer 24 is removed, so that the heat sink 22 is exposed from the second surface 24b of the encapsulation layer 24.

In an embodiment, the outer surface of the heat sink 22 and the second surface 24b of the encapsulation layer 24 are coplanar via a flattening process or a thinning process, that is, the outer surface of the heat sink 22 is flush with the second surface 24b of the encapsulation layer 24, such that the outer surface of the heat sink 22 is exposed from the encapsulation layer 24. For instance, part of material of the second surface 24b of the encapsulation layer 24 is removed by grinding or cutting, so that the outer surface of the heat sink 22 is flush with the second surface 24b of the encapsulation layer 24.

As shown in FIG. 2F, a plurality of conductive components 29 such as solder balls are placed on the ball placement pads 204 of the second side 20b of the carrier structure 20 to be connected to an electronic device (not shown) such as a circuit board in the subsequent process.

As shown in FIG. 2G-1, a singulation process is conducted along a cutting path S shown in FIG. 2F to obtain the electronic package 2.

In an embodiment, the supporting leg 23b on one side of the heat dissipation structure 23 is removed during the singulation process, such that the sheet-shaped body 23a is exposed from one side surface 24c of the encapsulation layer 24.

In addition, the supporting legs 23b of multiple sides of the heat dissipation structure 23 can also be removed during the singulation process, as an electronic package 3 shown in FIG. 2G-2, such that a sheet-shaped body 33a is exposed from multiple side surfaces 24c of the encapsulation layer 24.

Furthermore, a passive element 28 can be arranged on the first side 20a and/or the second side 20b of the carrier structure 20 according to requirements, as shown in FIG. 2G-2. For instance, the sheet-shaped body 33a of the heat dissipation structure 23 covers the passive element 28.

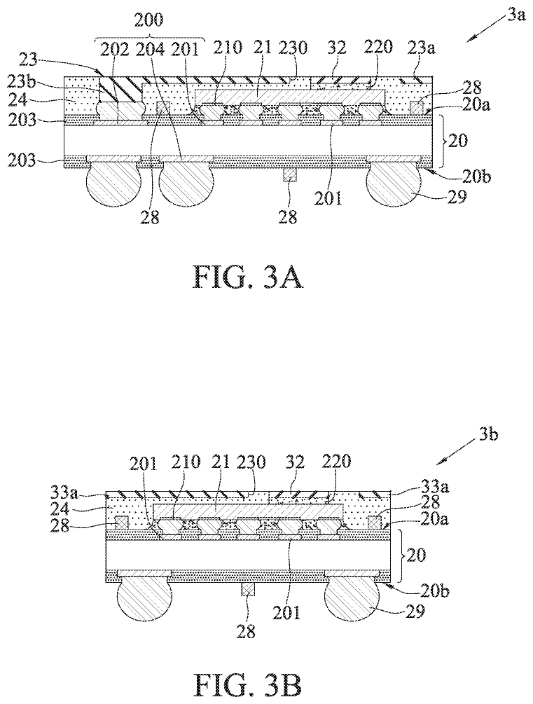

Moreover, as an electronic package 3a, 3b shown in FIG. 3A and FIG. 3B, when removing part of material of the second surface 24b of the encapsulation layer 24, part of material of a heat sink 32 can be removed at the same time, so that the outer surface of the heat sink 32 and the outer surface of the sheet-shaped body 23a, 33a of the heat dissipation structure 23 are coplanar, that is, the outer surface of the heat sink 32 is flush with the top surface of the sheet-shaped body 23a, 33a of the heat dissipation structure 23, such that the outer surface of the heat sink 32 and the top surface of the sheet-shaped body 23a, 33a of the heat dissipation structure 23 are exposed from the second surface 24b of the encapsulation layer 24.

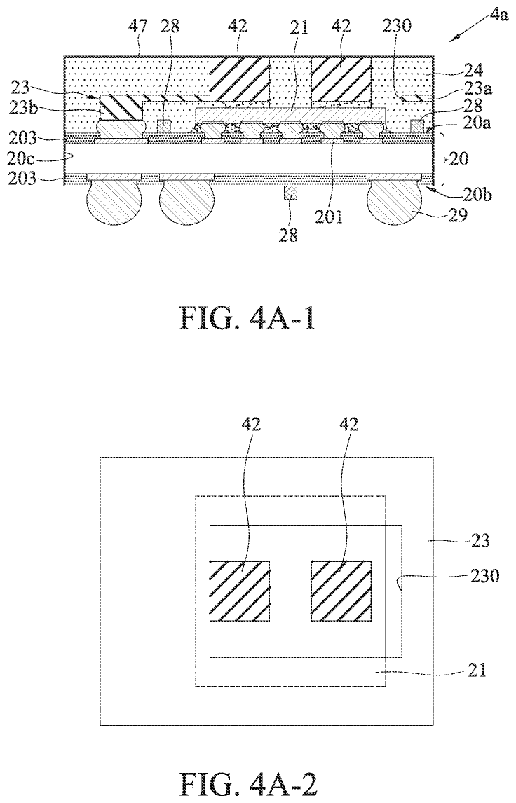

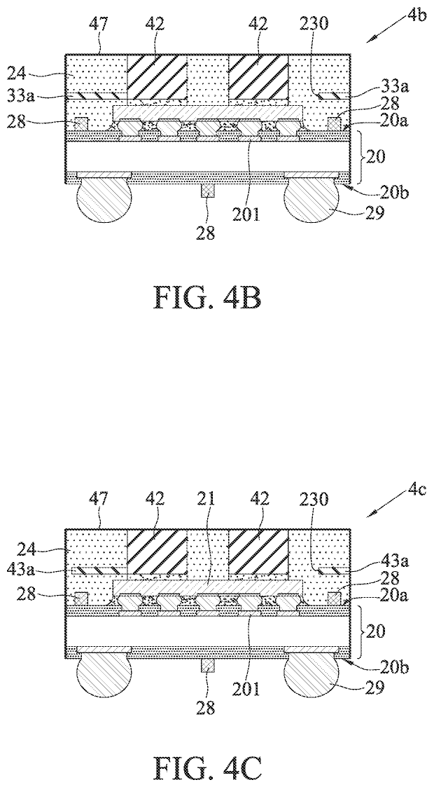

Please see FIG. 4A-1, FIG. 4B and FIG. 4C, which are schematic cross-sectional views illustrating an electronic package 4a, 4b, 4c according to a second embodiment of the present disclosure. The difference between the first embodiment and the second embodiment lies in the number of heat sinks, and other structures are substantially the same, so the similarities of the two embodiments will not be repeated below.

As shown in FIG. 4A-1, FIG. 4B, FIG. 4C and FIG. 4A-2 (the schematic partial top view of FIG. 4A-1), if the electronic component 21 has multiple heat sources of specific parts, a plurality of heat sinks 42 separated from each other can be formed in the opening 230 in the process shown in FIG. 2C-1, so that each of the heat sinks 42 is bonded onto the inactive surface 21b of the electronic component 21.

In an embodiment, a shielding layer 47 can be formed on the encapsulation layer 24 and in contact with the sheet-shaped body 23a, 33a, 43a, and that the shielding layer 47 extends onto a side surface 20c of the carrier structure 20. For instance, the material for forming the shielding layer 47 is such as gold (Au), silver (Ag), copper (Cu), nickel (Ni), iron (Fe), aluminum (Al), stainless steel (Steel Use Stainless [SUS]), and the like.

Besides, the shielding layer 47 can be formed by electroplating, coating, sputtering, chemical plating, electroless plating, vapor deposition, or the like. Alternatively, a metal cover plate or a conductive film can also be adapted as the shielding layer 47, and then the shielding layer 47 is arranged in a bonding/sticking manner.

In addition, as shown in FIG. 4C, if one end side of the sheet-shaped body 43a of the heat dissipation structure 23 is not provided with the supporting leg 23b, then the end side of the sheet-shaped body 43a is not in contact with the shielding layer 47 after the singulation process.

Moreover, the heat sink 42 can be in contact with or spaced apart from the sheet-shaped body 23a, 33a, 43a.

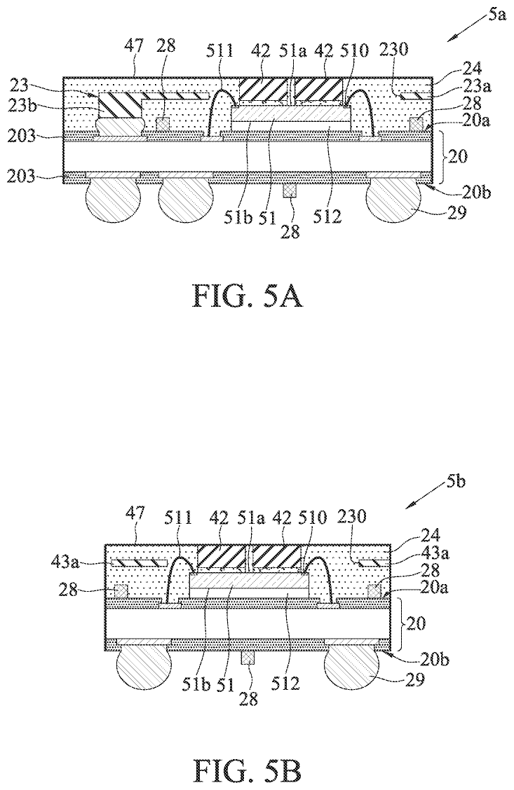

Please see FIG. 5A and FIG. 5B, which are schematic cross-sectional views illustrating an electronic package 5a, 5b according to a third embodiment of the present disclosure. The difference between the second embodiment and the third embodiment lies in the type of the electronic component, and other structures are substantially the same, so the similarities of the two embodiments will not be repeated below.

As shown in FIG. 5A and FIG. 5B, corresponding to the process shown in FIG. 2A, an electronic component 51 is electrically connected to the carrier structure 20 by wire bonding. The electronic component 51 has an active surface 51a and an inactive surface 51b opposing the active surface 51a.

In an embodiment, the electronic component 51 is disposed on the first side 20a of the carrier structure 20 via a bonding layer 512 such as a die attach film by the inactive surface 51b thereof, and then a plurality of wires 511 such as gold wires are bonded to electrode pads 510 and the electrical contact pads 201, so that the electronic component 51 is electrically connected to the circuit layer 200 of the carrier structure 20.

It should be understood that there are various ways for the electronic component to be electrically connected to the carrier structure 20, and the required types and quantity of electronic components can be connected on the carrier structure 20 without any special limits.

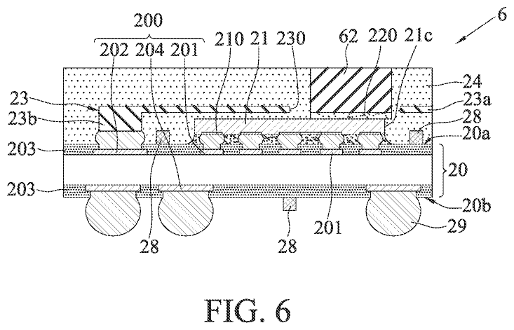

Please see FIG. 6, which is a schematic cross-sectional view illustrating an electronic package 6 according to a fourth embodiment of the present disclosure. The difference between the fourth embodiment and the aforementioned embodiments lies in the dimension of the heat sink, and other structures are substantially the same, so the similarities between the embodiments will not be repeated below.

As shown in FIG. 6, take the first embodiment for instance, the width of a heat sink 62 is increased, so that the heat sink 62 protrudes from a side surface 21c of the electronic component 21.

Therefore, in the manufacturing method of the present disclosure, the heat sink 22, 32, 42, 62 can be arranged according to the heat source of a specific part of the electronic component 21, 51, so the flexibility of use is great. Hence, compared to the prior art, the electronic package 2, 3, 3a, 3b, 4a, 4b, 4c, 5a, 5b, 6 of the present disclosure can effectively dissipate heat during operation.

In addition, by configurations of the heat sink 22, 32, 42, 62 and the heat dissipation structure 23, the electronic package 2, 3, 3a, 3b, 4a, 4b, 4c, 5a, 5b, 6 of the present disclosure can be applied with different types of packaging specifications, such as flip-chip packaging or wire-bonding packaging.

Furthermore, the heat dissipation structure 23 is embedded in the encapsulation layer 24, so that the large amount of heat generated during the operation of the electronic component 21, 51 and the passive element 28 can be quickly dissipated to the outside via the heat dissipation structure 23, so as to avoid damages to the electronic component 21, 51 and the passive element 28 or to avoid affecting product reliability.

Moreover, the manufacturing method of the present disclosure can use existing materials, processes and machines without adding new processes and materials or purchasing new equipment. Hence, the manufacturing method of the present disclosure can effectively control the cost of the processes, so that the electronic package 2, 3, 3a, 3b, 4a, 4b, 4c, 5a, 5b, 6 of the present disclosure is economical.

The present disclosure also provides an electronic package 2, 3, 3a, 3b, 4a, 4b, 4c, 5a, 5b, 6, which comprises: a carrier structure 20 having a circuit layer 200; at least one electronic component 21, 51 disposed on the carrier structure 20 and electrically connected to the circuit layer 200; at least one heat sink 22, 32, 42, 62 disposed on the electronic component 21, 51; an encapsulation layer 24 formed on the carrier structure 20 and covering the electronic component 21, 51 and the heat sink 22, 32, 42, 62; and a heat dissipation structure 23 embedded in the encapsulation layer 24.

The heat dissipation structure 23 has at least one opening 230, such that the heat sink 22, 32, 42, 62 is disposed in the opening 230.

In an embodiment, the electronic component 21, 51 is electrically connected to the circuit layer 200 via a plurality of conductive bumps 211 or a plurality of wires 511.

In an embodiment, a width D of the heat sink 22 is less than or equal to a width R of the electronic component 21.

In an embodiment, the heat sink 22, 32, 42 is bonded to the electronic component 21, 51 via an adhesive material 220.

In an embodiment, an outer surface of the heat sink 22, 42, 62 and an outer surface of the encapsulation layer 24 are coplanar.

In an embodiment, an outer surface of the heat sink 32, an outer surface of the heat dissipation structure 23 and an outer surface of the encapsulation layer 24 are coplanar.

In an embodiment, the heat dissipation structure 23 is exposed from a side surface 24c of the encapsulation layer 24.

In an embodiment, the electronic component 21 is covered by the heat dissipation structure 23.

In an embodiment, the heat dissipation structure 23 comprises a sheet-shaped body 23a, 33a, 43a surrounding the heat sink 22, 32, 42, 62. For instance, the heat dissipation structure 23 further comprises at least one supporting leg 23b connected to the sheet-shaped body 23a, 33a, 43a, and the supporting leg 23b is bonded to the carrier structure 20.

In an embodiment, a plurality of the heat sinks 42 are arranged on the electronic component 21, 51.

In an embodiment, the electronic package 4a, 4b, 4c, 5a, 5b further comprises a shielding layer 47 formed on the encapsulation layer 24 and in contact with the heat dissipation structure 23.

In an embodiment, the heat sink 62 protrudes from a side surface 21c of the electronic component 21.

To sum up, in the electronic package and the manufacturing method thereof according to the present disclosure, the heat sink can be arranged according to the heat source of a specific part of the electronic component, so the flexibility of use is great and the arrangement area is small. Hence, the electronic package of the present disclosure can effectively dissipate heat during operation and have a low cost, and can be applied with various types of packaging specifications.

Besides, the manufacturing method of the present disclosure can use existing materials, processes and machines without adding new processes and materials or purchasing new equipment. Hence, the manufacturing method of the present disclosure can effectively control the cost of the processes, so that the electronic package of the present disclosure is economical.

The above embodiments are set forth to illustrate the principles of the present disclosure and the effects thereof, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. An electronic package, comprising:
a carrier structure having a circuit layer;
an electronic component disposed on the carrier structure and electrically connected to the circuit layer;
a heat sink disposed on the electronic component;
an encapsulation layer formed on the carrier structure and covering the electronic component and the heat sink; and
a heat dissipation structure having an opening and embedded in the encapsulation layer, wherein the heat sink is located in the opening.

2. The electronic package of claim 1, wherein the electronic component is electrically connected to the circuit layer via a plurality of conductive bumps or a plurality of wires.

3. The electronic package of claim 1, wherein a width or an area of the heat sink is less than or equal to a width or an area of the electronic component.

4. The electronic package of claim 1, wherein the heat sink is bonded to the electronic component via an adhesive material.

5. The electronic package of claim 1, wherein an outer surface of the heat sink and an outer surface of the encapsulation layer are coplanar.

6. The electronic package of claim 1, wherein an outer surface of the heat sink, an outer surface of the heat dissipation structure and an outer surface of the encapsulation layer are coplanar.

7. The electronic package of claim 1, wherein the heat dissipation structure is exposed from a side surface of the encapsulation layer.

8. The electronic package of claim 1, wherein the electronic component is covered by the heat dissipation structure.

9. The electronic package of claim 1, wherein the heat dissipation structure comprises a sheet-shaped body surrounding the heat sink.

10. The electronic package of claim 9, wherein the heat dissipation structure further comprises at least one supporting leg connected to the sheet-shaped body, and the supporting leg is bonded to the carrier structure.

11. The electronic package of claim 1, wherein a plurality of the heat sinks are arranged on the electronic component.

12. The electronic package of claim 1, further comprising a shielding layer formed on the encapsulation layer and in contact with the heat dissipation structure.

13. The electronic package of claim 1, wherein the heat sink protrudes from a side surface of the electronic component.

14. A method of manufacturing an electronic package, comprising:
providing a carrier structure having a circuit layer;
disposing an electronic component and a heat dissipation structure having an opening on the carrier structure, wherein the electronic component is electrically connected to the circuit layer, wherein a position of the opening corresponds to the electronic component, and the electronic component is correspondingly exposed from the opening;
disposing at least one heat sink in the opening and on the electronic component; and
forming an encapsulation layer on the carrier structure to cover the electronic component, the heat dissipation structure and the heat sink.

15. The method of claim 14, wherein the electronic component is electrically connected to the circuit layer via a plurality of conductive bumps or a plurality of wires.

16. The method of claim 14, wherein a width or an area of the heat sink is less than or equal to a width or an area of the electronic component.

17. The method of claim 14, wherein the heat sink is bonded to the electronic component via an adhesive material.

18. The method of claim 14, wherein an outer surface of the heat sink and an outer surface of the encapsulation layer are coplanar.

19. The method of claim 14, wherein an outer surface of the heat sink, an outer surface of the heat dissipation structure and an outer surface of the encapsulation layer are coplanar.

20. The method of claim 14, wherein the heat dissipation structure is exposed from a side surface of the encapsulation layer.

21. The method of claim 14, wherein the electronic component is covered by the heat dissipation structure.

22. The method of claim 14, wherein the heat dissipation structure comprises a sheet-shaped body surrounding the heat sink.

23. The method of claim 22, wherein the heat dissipation structure further comprises at least one supporting leg connected to the sheet-shaped body, and the supporting leg is bonded to the carrier structure.

24. The method of claim 14, wherein a plurality of the heat sinks are arranged on the electronic component.

25. The method of claim 14, further comprising forming a shielding layer on the encapsulation layer, wherein the shielding layer is in contact with the heat dissipation structure.

26. The method of claim 14, wherein the heat sink protrudes from a side surface of the electronic component.
